(19) United States
(12) Patent Application Publication
(10) Pub. No.: US 2024/0198859 A1
(43) Pub. Date: Jun. 20, 2024

(54) BATTERY SYSTEM AND THE METHOD FOR OPERATING THE SAME

(71) Applicant: Volvo Car Corporation, Goteborg (SE)

(72) Inventors: Jonas FORSSELL, Göteborg (SE); Markus EKSTRÖM, Göteborg (SE); Aditya Pratap SINGH, Göteborg (SE); Ivan REXED, Göteborg (SE)

(21) Appl. No.: 18/539,691

(22) Filed: Dec. 14, 2023

(30) Foreign Application Priority Data
Dec. 14, 2022 (EP) 22213478.5

(51) Int. Cl. B60L 58/24; G01R 31/367; G01R 31/3842; G01R 31/396

(52) U.S. Cl. CPC B60L 58/24; G01R 31/367; G01R 31/3842; G01R 31/396; B60L 2240/547; B60L 2240/549

(57) ABSTRACT

According to an embodiment, it is a method comprising, requesting a first cell level inverter unit to enable a first discharge current and a second cell level inverter unit to disable a second discharge current, and requesting the second cell level inverter unit to enable the second discharge current and the first cell level inverter unit to disable the first discharge current, and wherein the method is operable for operating a battery system comprising a plurality of battery cells comprising a first single battery cell and a second single battery cell; and a plurality of cell level inverter units comprising the first cell level inverter unit and the second cell level inverter unit; and wherein each of a cell level inverter unit of the plurality of cell inverter units being electrically coupled to at least a single battery cell out of the plurality of battery cells.

### CROSS-REFERENCE TO RELATED APPLICATIONS

This application claims the benefit of European Patent Application Number 22213478.5, filed on Dec. 14, 2022, which is hereby incorporated by reference in its entirety.

### FIELD OF INVENTION

The present disclosure relates to a battery system and a method for operating the battery system comprising a plurality of battery cells and a plurality of cell-level inverter units.

### BACKGROUND

It is known that starting a vehicle having a battery system in cold environments is challenging. This is mainly due to the sluggish reaction of kinetics to the battery system at low temperatures.

Therefore, there is a need for a battery system and a method for operating the battery system such that the battery system may be started in a comparatively cold environment.

### SUMMARY

The present disclosure relates to a method for operating a battery system comprising a plurality of battery cells and a plurality of cell-level inverter units, each of the cell-level inverter units being electrically coupled to a single battery cell out of the plurality of battery cells or to a group of battery cells out of the plurality of battery cells.

The present disclosure is additionally directed to a corresponding data processing apparatus, a corresponding computer program, and a corresponding computer-readable storage medium.

Moreover, the present disclosure relates to a battery system comprising a plurality of battery cells and a plurality of cell-level inverter units, wherein each of the cell-level inverter units is electrically coupled to a single battery cell out of the plurality of battery cells or to a group of battery cells out of the plurality of battery cells.

Furthermore, the present disclosure is directed to a drivetrain for an electric vehicle and a vehicle.

Vehicles using one or more electric traction motors are generally known. Such vehicles, be it battery electric vehicles or hybrid electric vehicles, usually comprise a battery system for storing energy necessary to power the one or more traction motors. Such a battery system may also be called a traction battery system.

It is also known that starting a vehicle having such a battery system in cold environments is challenging. This is mainly due to the sluggish reaction of kinetics to the battery system at low temperatures.

In order to be able to provide sufficient motor torque and motor power when starting the vehicle, comparatively high currents need to be extracted from the battery system. In a cold environment, this may compromise the battery life, i.e. reduce the service life of the battery.

In order to solve this problem, heating devices have been proposed such that traction battery systems may be heated before actually being started, i.e. before being used for powering a traction motor. However, providing a heating device increases the structural complexity of the battery system.

It is, thus, an objective of the present disclosure to provide a battery system which at the same time is structurally simple and may be started in a comparatively cold environment without causing an excessive reduction of battery life.

The problem is at least partially solved or alleviated by the subject matter of the independent claims of the present disclosure, wherein further examples are incorporated in the dependent claims.

According to the first aspect, there is provided a method for operating a battery system. The battery system comprises a plurality of battery cells and a plurality of cell-level inverter units. Each of the cell-level inverter units is electrically coupled to a single battery cell out of the plurality of battery cells or to a group of battery cells out of the plurality of battery cells. The method comprises:
requesting a first cell-level inverter unit to enable a first discharge current and requesting a second cell-level inverter unit to disable a second discharge current, and
requesting the second cell-level inverter unit to enable the second discharge current and requesting the first cell-level inverter unit to disable the first discharge current.

It is understood that the first cell-level inverter unit is electrically coupled to a first single battery cell or a first group of battery cells. In the same manner, the second cell-level inverter unit is electrically coupled to a second single battery cell or a second group of battery cells. Thus, the first discharge current, if enabled, originates from the first single battery cell or the first group of battery cells. The second discharge current, if enabled, originates from the second single battery cell or the second group of battery cells. This means that in a first step, the first single battery cell or the first group of battery cells is enabled to be used to provide a current which may be used for powering an electric traction machine. In a second step, the second single battery cell or the second group of battery cells is enabled to be used to provide a current which may be used for powering an electric traction machine. It is noted that the first single battery and the second single battery are overlap-free. This means that one specific battery cell of the battery system is either the first single battery cell or the second single battery cell. The same applies to the first group of battery cells and the second group of battery cells. Each specific battery cell of the battery system either forms part of the first group of battery cells or the second group of battery cells. Thus, while the first single battery cell or the first group of battery cells is used to provide a current, the second single battery cell or the second group of battery cells is not used for providing a current. In a case in which the second single battery cell or the second group of battery cells is used to provide a current, the first single battery cell or the first group of battery cells is not used. Consequently, each of the batteries cells only has to provide a current for a comparatively short time span. The battery cells not being used to provide a current are able to recover from the thermal and electrical stress that the withdrawal of current imposes. After the recovery, the battery cells are again able to provide a stable voltage. When applying this method in a comparatively cold environment, the negative influences of the cold environment on the starting of the battery system are mitigated and, as a consequence, the battery life is enhanced. This is especially the case when comparing the method of the present disclosure to known methods according to which a current is withdrawn from all battery cells at the same time. Additionally, also as compared to known battery systems, since only a portion of battery cells is used at each point in time, comparatively high currents have to be provided by these battery cells. This leads to an effective and efficient heating of the battery system.

A comparatively cold environment may be understood as an environment having an ambient temperature of −20° C. or lower or temperatures of −25° C. or lower. Analogously, comparatively low temperatures may be understood as temperatures of −20° C. or lower or temperatures of −25° C. or lower.

In an example, requesting the first cell-level inverter unit to enable the first discharge current and requesting the second cell-level inverter unit to enable the second discharge current is performed in accordance with a predefined pattern. In a case in which the predefined pattern is used when starting the battery system in a comparatively cold environment, the predefined pattern may also be called a cold start protocol. The predefined pattern may be characterized by at least one of a duration during which the first cell level inverter unit is requested to enable the first discharge current, a duration during which the second cell level inverter unit is requested to enable the second discharge current, a time span between requesting the first cell level inverter unit to enable the first discharge current and requesting the second cell level inverter unit to enable the second discharge current, and an order according to which the first cell-level inverter unit and the second cell-level inverter unit are requested to enable the corresponding discharge current. The pattern may also be a function of an environmental parameter, e.g. temperature.

In an example, the first discharge current is enabled for a predefined time. Additionally, or alternatively, the second discharge current is enabled for a predefined time. This means that the corresponding battery cells are only providing the first discharge current or the second discharge current for a predefined time which may be relatively short, e.g., a few milliseconds to a few seconds. Thereafter, other battery cells are used. This has the effect that even in a relatively cold environment, a current of sufficient magnitude may be provided without compromising the battery life.

In an example, the first discharge current is enabled until a first operational voltage of the first, single battery cell or the first group of battery cells falls below a predefined first cut-off voltage. Additionally, or alternatively, the second discharge current is enabled until a second operational voltage of the second, single battery cell or the second group of battery cells falls below a predefined second cut-off voltage. In this context, the operational voltage of the first, single battery cell or the first group of battery cells or the second single battery cell or the second group of battery cells may be taken as an indicator of the stress to which the respective battery cell group of battery cells is subject. The first cut-off voltage and/or the second cut-off voltage is chosen such that this stress does not exceed a predefined level. In other words, the respective battery cells are not used for providing a currents, if the risk of compromising the battery life is too high. Overall, such a battery system may be started in a comparatively cold environment without compromising the battery life.

In an example, the first discharge current is enabled until a first electric charge quantity is withdrawn from the first, single battery cell or the first group of battery cells. Additionally, or alternatively, the second discharge current is enabled until a second electric charge quantity is withdrawn from the second, single battery cell or the second group of battery cells. Thus, a fixed charge quantity is withdrawn from each battery cell before it is disabled, and different battery cells are used for providing current. In a cold environment, stress on a specific battery cell increases with the charge quantity being withdrawn therefrom. Thus, by limiting the charge quantity to be withdrawn, also the stress on the respective battery cells is reduced. When applying this in a comparatively cold environment, negative effects on the battery life are eliminated or at least mitigated. In other words, battery life is enhanced.

In the above examples, stress to which a battery cell is subject may be thermal stress and/or electrical stress.

In an example, the first, single battery cell or the first group of battery cells and the second, single battery cell or the second group of battery cells are arranged adjacent to one another. In other words, the battery cells are arranged in a row or stacked. This has the effect that heat being generated by one battery cell due to the withdrawal of a current, may be used in order to warm up neighboring battery cells. In such a configuration, a separate heating device is not necessary. Consequently, the corresponding battery system is structurally simple.

In an example, the method further comprises:
receiving or determining an environmental temperature and
performing the method if the environmental temperature is inferior to an environmental temperature threshold or, otherwise, abandoning the method.

This means that the present method may only be performed in a case in which the battery system is located in a comparatively cold environment. As has already been mentioned before, the temperature threshold may be −20° C. In another example, the temperature threshold may be −25° C. Put otherwise, the method according to the present disclosure is only used, if this is necessary due to an environmental temperature.

In an example, the method further comprises:
receiving or determining a battery system temperature and
performing the method if the battery system temperature is inferior to a battery system temperature threshold or, otherwise, abandoning the method.

This means that the present method may only be performed in a case in which the battery system is comparatively cold. As has already been mentioned before, the temperature threshold may be −20° C. In another example, the temperature threshold may be −25° C. Put otherwise, the method according to the present disclosure is only used, if this is necessary due to the temperature of the battery system.

It is noted that the method according to the present disclosure may as well be performed as function of both the environmental temperature and the battery system temperature.

In an example, the method further comprises subsequently requesting a third cell-level inverter unit being electrically coupled to a third single battery cell or a third group of battery cells, to enable a third discharge current originating from the third single battery cell or the third group of battery cells. Additionally, the first cell-level inverter unit is requested to disable the first discharge current, and the second cell-level inverter unit is requested to disable the second discharge current. Thus, the method may also be applied to a battery system having three single battery cells or three groups of battery cells. In this context, at any given point in time, only one of the single battery cells or only one of the groups of battery cells is used in order to provide a discharge current. The remaining single battery cells or the remaining groups of battery cells are not used. Also in this example, the battery system may be started in a comparatively cold environment. At the same time, negative influences on the battery life are reduced or eliminated.

It is understood that the method according to the present disclosure may as well be used for battery systems having four or more single battery cells or four or more groups of battery cells. For example, the battery system may comprise 4 to 200 single battery cells. In another example, the battery system may comprise 5 to 20 groups of battery cells. The effects and advantages are the same as has already been explained above.

It is noted that the term discharge current as used in the present disclosure may relate to an AC signal. Moreover, the term discharge current may relate to a group of AC signals differing, for example in their respective phase. In an example, the term discharge current relates to a group of three AC signals differing in their respective phase and being configured for powering an electric traction machine.

In a case in which there are three or more single battery cells or groups of battery cells, the discharge current may be provided by one of the single battery cells or the group of the various cells in a predefined order. If at the same time, the battery cells are arranged in a row, the order of using the battery cells may correspond to a line-up direction of the row.

The method may be at least partly computer-implemented, and may be implemented in software or in hardware, or in software and hardware. Further, the method may be carried out by computer program instructions running on means that provide data processing functions. The data processing means may be a suitable computing means, such as an electronic control module etc., which may also be a distributed computer system. The data processing means or the computer, respectively, may comprise one or more of a processor, a memory, a data interface, or the like.

According to a second aspect, there is provided a data processing apparatus comprising means for carrying out the method of the present disclosure. Thus, when using such a data processing apparatus in a situation of a comparatively cold environment, the negative influences of the cold environment on the starting of the battery system are mitigated and, as a consequence, the battery life is enhanced.

According to a third aspect, there is provided a computer program comprising instructions which, when the computer program is executed by a computer, cause the computer to carry out the method of the present disclosure. Using such a computer program in a situation of a comparatively cold environment has the effect that the negative influences of the cold environment on the starting of the battery system are mitigated and, as a consequence, the battery life is enhanced.

According to a fourth aspect, there is provided a computer-readable storage medium comprising instructions which, when executed by a computer, cause the computer to carry out the method of the present disclosure. Such a computer-readable storage leads to a reduction of negative influences of a cold environment on the starting of the battery system, if applied in a relatively cold environment. Consequently, the battery life is enhanced.

According to a fifth aspect, there is provided a battery system comprising a plurality of battery cells and a plurality of cell-level inverter units. Each of the cell-level inverter units is electrically coupled to a single battery cell out of the plurality of battery cells or to a group of battery cells out of the plurality of battery cells. The battery system also comprises a data processing apparatus according to the present disclosure. The data processing apparatus is communicatively coupled to each of the cell-level inverter units. Such a battery system is particularly well-suited for being used in a comparatively cold environment. In more detail, when starting such a battery system in a comparatively cold environment, negative influences on the service life of the battery system are comparatively small. This is especially the case when comparing the battery system according to the present disclosure to a known battery systems.

According to the sixth aspect, there is provided a drivetrain for an electric vehicle. The drivetrain comprises a battery system according to the present disclosure and an electric traction motor being electrically coupled to the battery system. Due to the effects that have already been explained above, such a drivetrain has a comparatively long service life.

According to a seventh aspect, there is provided a vehicle comprising a drivetrain of the present disclosure. Since the drivetrain has a comparatively long service life, and also the vehicle can enjoy a relatively long service life.

According to an embodiment, it is a method comprising requesting a first cell level inverter unit to enable a first discharge current and a second cell level inverter unit to disable a second discharge current, and requesting the second cell level inverter unit to enable the second discharge current and the first cell level inverter unit to disable the first discharge current; and wherein the method is operable for operating a battery system comprising a plurality of battery cells comprising a first single battery cell and a second single battery cell and a plurality of cell level inverter units comprising the first cell level inverter unit and the second cell level inverter unit; and wherein each of a cell level inverter unit of the plurality of cell level inverter units being electrically coupled to at least a single battery cell out of the plurality of battery cells.

According to an embodiment, it is a system comprising, a plurality of battery cells comprising a first single battery cell and a second single battery cell and a plurality of cell level inverter units comprising a first cell level inverter unit and a second cell level inverter unit, wherein each of a cell level inverter unit out of the plurality of cell level inverter units is electrically coupled to at least a single battery cell out of the plurality of battery cells; and a data processing apparatus, wherein the data processing apparatus is communicatively coupled to one or more of the plurality of the cell level inverter units; and wherein the data processing apparatus is operable to, request the first cell level inverter unit to enable a first discharge current and the second cell level inverter unit to disable a second discharge current, and request the second cell level inverter unit to enable the second discharge current and the first cell level inverter unit to disable the first discharge current; and wherein the system is operable to be a battery system.

According to an embodiment, it is a non-transitory computer readable medium operations having stored thereon instructions executable by a computer system to perform operations comprising requesting a first cell level inverter unit to enable a first discharge current and a second cell level inverter unit to disable a second discharge current, and requesting the second cell level inverter unit to enable the second discharge current and the first cell level inverter unit to disable the first discharge current; and wherein the instructions are operable for operating a battery system comprising a plurality of battery cells comprising a first single battery cell and a second single battery cell; and a plurality of cell level inverter units comprising the first cell level inverter unit and the second cell level inverter unit; and wherein each of a cell level inverter unit of the plurality of cell level inverter units being electrically coupled to at least a single battery cell out of the plurality of battery cells.

According to an embodiment, it is a method comprising requesting a first cell level inverter unit to enable a first discharge current and a second cell level inverter unit to disable a second discharge current, and requesting the second cell level inverter unit to enable the second discharge current and the first cell level inverter unit to disable the first discharge current; and wherein the method is operable for operating a battery system comprising a plurality of battery cells comprising a first single battery cell and a second single battery cell and a plurality of cell level inverter units comprising the first cell level inverter unit and the second cell level inverter unit; and wherein each of a cell level inverter unit of the plurality of cell level inverter units being electrically coupled to a group of battery cells out of the plurality of battery cells.

According to an embodiment, it is a system comprising, a plurality of battery cells comprising a first single battery cell and a second single battery cell and a plurality of cell level inverter units comprising a first cell level inverter unit and a second cell level inverter unit, wherein each of a cell level inverter unit out of the plurality of cell level inverter units is electrically coupled to a group of battery cells out the plurality of battery cells; and a data processing apparatus, wherein the data processing apparatus is communicatively coupled to one or more of the plurality of the cell level inverter units; and wherein the data processing apparatus is operable to, request the first cell level inverter unit to enable a first discharge current and the second cell level inverter unit to disable a second discharge current, and request the second cell level inverter unit to enable the second discharge current and the first cell level inverter unit to disable the first discharge current; and wherein the system is operable to be a battery system.

According to an embodiment, it is a non-transitory computer readable medium operations having stored thereon instructions executable by a computer system to perform operations comprising requesting a first cell level inverter unit to enable a first discharge current and a second cell level inverter unit to disable a second discharge current, and requesting the second cell level inverter unit to enable the second discharge current and the first cell level inverter unit to disable the first discharge current; and wherein the instructions are operable for operating a battery system comprising a plurality of battery cells comprising a first single battery cell and a second single battery cell; and a plurality of cell level inverter units comprising the first cell level inverter unit and the second cell level inverter unit; and wherein each of a cell level inverter unit of the plurality of cell level inverter units being electrically coupled to a group of battery cells out of the plurality of battery cells.

It should be noted that the above examples may be combined with each other irrespective of the aspect involved.

These and other aspects of the present disclosure will become apparent from and elucidated with reference to the examples described hereinafter.

### BRIEF DESCRIPTION OF DRAWINGS

Examples of the disclosure will be described in the following with reference to the following drawings.

FIG. 1 shows a vehicle according to the present disclosure having a drivetrain according to the present disclosure with a battery system according to the present disclosure, wherein the battery system may be operated using a method according to the present disclosure.

FIG. 2 shows a more detailed view of the battery system of FIG. 1 along direction II of FIG. 1.

FIG. 3 shows an evolution of an output voltage of a known battery cell over time at room temperature and at a temperature of −20° C.

FIG. 4 illustrates the method according to the present disclosure by an evolution of output voltages of a plurality of battery cells.

The Figures are merely schematic representations and serve only to illustrate examples of the disclosure. Identical or equivalent elements are in principle provided with the same reference signs.

### DETAILED DESCRIPTION

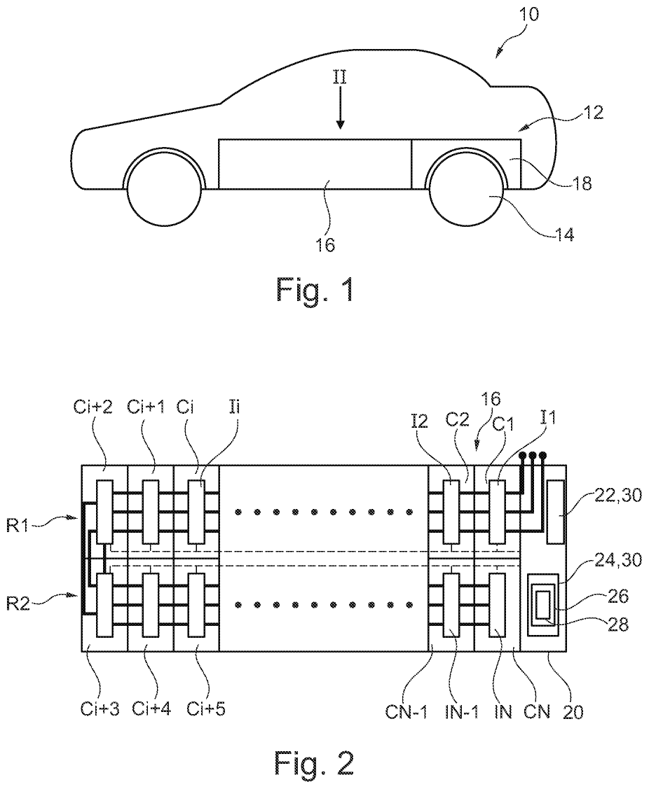

FIG. 1 shows a vehicle 10 being a battery electric vehicle.

The vehicle 10 comprises a drivetrain 12 which is configured for propelling the rear wheels 14 of the vehicle 10.

The drivetrain comprises a battery system 16 and an electric traction motor 18 being electrically coupled to the battery system 16.

The battery system 16 is shown in more detail in FIG. 2.

The battery system 16 comprises a plurality of battery cells being denoted C1 to CN. For the ease of representation, only some of the battery cells C1 to CN are represented or shown in FIG. 2. In a more general way, the battery cells may be denoted Ci, wherein i is a counting index.

In the present example, the battery cells C1 to CN are arranged in two parallel rows R1, R2. It is understood that this is just an example and the battery cells C1 to CN can as well be arranged in a single row or in three or more rows.

Each of the battery cells C1 to CN is equipped with a cell-level inverter unit being denoted I1 to IN. This means that each cell-level inverter unit I1 to IN is electrically connected to the poles of the associated battery cell C1 to CN.

Each of the cell-level inverter units I1 to IN is configured to convert a direct current signal being provided by the associated battery cell C1 to CN into an alternating current signal or even a group of alternating current signals. In the present example, each of the cell-level inverter units I1 to IN is configured to provide three alternating current signals of different phases.

These alternating current signals may be directly used in order to power the traction motor 18.

The battery system 16 additionally comprises a data processing apparatus 20.

Generally speaking, the data processing apparatus 20 is configured to control the cell-level inverter units I1 to IN, i.e. the data processing apparatus 20 is configured to control the drivetrain 12.

To this end, the data processing apparatus 20 is communicatively coupled to each of the cell-level inverter units I1 to IN. Corresponding communication lines are illustrated by dashed lines in FIG. 2.

The data processing apparatus 20 comprises a data processing unit 22 and a data storage unit 24.

The data storage unit 24 comprises a computer-readable storage medium 26.

On the computer-readable storage medium 26, there is provided a computer program 28 comprising instructions which, when the computer program is executed by the data processing unit 22 or, more generally, a computer, cause the computer or the data processing unit 22 to carry out the method for operating a battery system.

Thus, also the computer-readable storage medium 26 comprises instructions which, when executed by the data processing unit 22 or a computer, cause the data processing unit 22 or the computer to carry out the method for operating a battery system.

Consequently, the data processing unit 22 and the data storage unit 24 form means 30 for carrying out the method for operating a battery system.

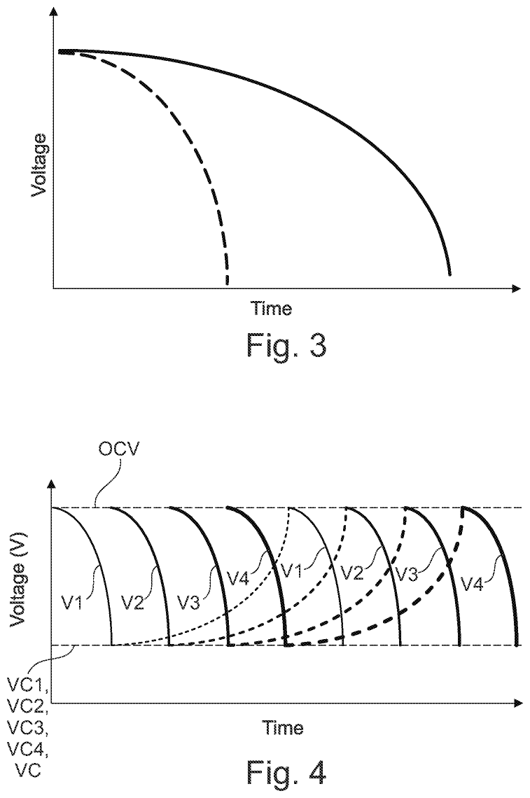

Before explaining the method for operating a battery system in more detail, reference is made to FIG. 3.

FIG. 3 shows an evolution of a voltage of a generally known battery cell over time, while a current is withdrawn from the battery cell. In other words, FIG. 3 shows the evolution of a voltage of the battery cell while the battery cell is used.

The diagram of FIG. 3 comprises two curves. The first curve being represented in a solid line represents the evolution of the voltage if the battery cell is discharged at room temperature.

The second curve being represented in dashed line represents the evolution of the voltage, if the battery cell is discharged at −20° C.

It is, thus, easily visible from the diagram of FIG. 3 that in a cold environment, the voltage of a battery cell drops significantly faster and earlier than at room temperature. Since in standard use cases of a battery cell, a minimum voltage is required, e.g. for powering an electric motor, only a significantly reduced capacity of the battery cell can be used in a cold environment.

The behavior as illustrated in FIG. 3 may describe the behavior of each of the battery cells C1 to CN of the battery system 16.

In the following, the method for operating the battery system will be explained in connection with FIG. 4.

This method makes use of the fact that each of the battery cells C1 to CN is equipped with a cell-level inverter unit I1 to IN.

For the purpose of illustration, the method will be illustrated for a battery system 16 comprising four battery cells C1 to C4 only. It is understood that in reality, the battery system 16 can comprise up to 150 or 200 battery cells.

As has been mentioned before, the method for operating the battery system 16 is especially suitable for operating the battery system 16 in a cold environment. More precisely, the method for operating the battery system is directed to a cold start situation for a battery system 16. This means that the battery system 16 is started and to be used in a cold environment, e.g. at an environmental temperature of −20°.

Consequently, in the first step of the method, an environmental temperature is received or determined.

If the environmental temperature is found to equal or exceed the predefined environmental temperature threshold, in the present example −20° C., the method is abandoned.

Only if the environmental temperature is found to be lower than −20° C., the method is continued.

It is noted that in an alternative, instead of the environmental temperature, a battery system temperature is used. Thus, the method is abandoned, if the battery system temperature is found to equal or exceed a battery system temperature threshold.

Only if the battery system temperature is lower than the battery system temperature threshold, the method is continued.

In case the method is continued, the next step is performed.

In this step, the first cell-level inverter unit I1 being electrically coupled to the first single battery cell C1 is requested to enable a first discharge current originating from the first single battery cell C1.

At the same time, the second cell-level inverter unit I2 being electrically coupled to the second single battery cell C2 is requested to disable a second discharge current originating from the second single battery cell C2.

Moreover, the third cell-level inverter unit I3 being electrically coupled to the third single battery cell C3 is requested to disable a third discharge current originating from the third single battery cell C3.

Additionally, the fourth cell-level inverter unit I4 being electrically coupled to the fourth single battery cell C4 is requested to disable a fourth discharge current originating from the fourth single battery cell C4.

Consequently, at this stage of the method, only the first battery cell C1 delivers a discharge current which is used for powering the electric traction motor 18.

It is understood that the first discharge current is of sufficient magnitude to perform this task. It is also understood that compared to known methods for operating a battery system, wherein all battery cells deliver a current at the same time, the first discharge current is of relatively high magnitude.

Thereafter, in a next step, the first cell-level inverter unit I1 being electrically coupled to the first single battery cell C1 is requested to disable the first discharge current originating from the first single battery cell C1.

At the same time, the second cell-level inverter unit I2 being electrically coupled to the second single battery cell C2 is requested to enable a second discharge current originating from the second single battery cell C2.

As before, the third cell-level inverter unit I3 being electrically coupled to the third single battery cell C3 is requested to disable a third discharge current originating from the third single battery cell C3 and the fourth cell-level inverter unit I4 being electrically coupled to the fourth single battery cell C4 is requested to disable a fourth discharge current originating from the fourth single battery cell C4.

Consequently, at this stage of the method, only the second battery cell C2 delivers a discharge current which is used for powering the electric traction motor 18.

It is again understood that the second discharge current is of sufficient magnitude to perform this task. It is also understood that compared to a known methods for operating a battery system, wherein all battery cells deliver a current at the same time, the second discharge current is of relatively high magnitude.

Thereafter, in a following step, the first cell-level inverter unit I1 being electrically coupled to the first single battery cell C1 is requested to disable the first discharge current originating from the first single battery cell C1.

At the same time, the second cell-level inverter unit I2 being electrically coupled to the second single battery cell C2 is requested to disable a second discharge current originating from the second single battery cell C2.

However, now the third cell-level inverter unit I3 being electrically coupled to the third single battery cell C3 is requested to enable a third discharge current originating from the third single battery cell C3.

The fourth cell-level inverter unit I4 being electrically coupled to the fourth single battery cell C4 is still requested to disable a fourth discharge current originating from the fourth single battery cell C4.

Consequently, at this stage of the method, only the third battery cell C3 delivers a discharge current which is used for powering the electric traction motor 18.

It is again understood that the third discharge current is of sufficient magnitude to perform this task. It is also understood that compared to a known methods for operating a battery system, wherein all battery cells deliver a current at the same time, the third discharge current is of relatively high magnitude.

Subsequently, in a next step, the first cell-level inverter unit I1 being electrically coupled to the first single battery cell C1 is requested to disable the first discharge current originating from the first single battery cell C1.

At the same time, the second cell-level inverter unit I2 being electrically coupled to the second single battery cell C2 is requested to disable a second discharge current originating from the second single battery cell C2.

The third cell-level inverter unit I3 being electrically coupled to the third single battery cell C3 is requested to disable a third discharge current originating from the third single battery cell C3.

However, the fourth cell-level inverter unit I4 being electrically coupled to the fourth single battery cell C4 is requested to enable a fourth discharge current originating from the fourth single battery cell C4.

Consequently, at this stage of the method, only the fourth battery cell C4 delivers a discharge current which is used for powering the electric traction motor 18.

It is again understood that the fourth discharge current is of sufficient magnitude to perform this task. It is also understood that compared to a known methods for operating a battery system, wherein all battery cells deliver a current at the same time, the fourth discharge current is of relatively high magnitude.

In each of the steps as mentioned before, the discharge current of the respective battery cell C1, C2, C3, C4 is provided until a respective first operational voltage V1 of the first battery cell C1 falls below a first cut-off voltage VC1, a respective second operational voltage V2 of the second battery cell C2 falls below a second cut-off voltage VC2, a respective third operational voltage V3 of the third battery cell C3 falls below a third cut-off voltage VC3 or a respective fourth operational voltage V4 of the fourth battery cell C4 falls below a fourth cut-off voltage VC4.

The voltages V1, V2, V3, V4 are illustrated in FIG. 4.

In the present example, all the cut-off voltages VC1, VC2, VC3, VC4 are the same and are denoted VC.

Moreover, FIG. 4 illustrates an open circuit voltage OCV of each of the battery cells C1, C2, C3, C4. For the ease of explanation, it is assumed that the open circuit voltage OCV is the same for each of the battery cells C1, C2, C3, C4.

In summary, the battery cells C1, C2, C3, C4 are used in the order C1-C2-C3-C4.

In other words, the method for operating the battery system involves a predefined pattern of requesting the cell-level inverter unit I1, I2, I3, I4 to enable the corresponding first to fourth discharge current.

It is noted that FIG. 4 shows two cycles of the above pattern, i.e. C1-C2-C3-C4-C1-C2-C3-C4.

In other examples, also other patterns are possible, for example C1-C3-C4-C2 or C1-C4-C2-C3 or C4-C3-C2-C1.

In the present example, the battery cells C1 to C4 are arranged in one row adjacent to one another. Since withdrawing a discharge current from each of the battery cells C1 to C4 generates heat, this heat also warms neighboring battery cells of the battery cell from which the discharge current is withdrawn.

It is noted that in an alternative, one, several ones or all of the first discharge current, the second discharge current, the third discharge current and the fourth discharge current may as well be enabled for a predefined time. This means that the cut-off voltages are replaced by corresponding cut-off times.

In a further alternative, one, several ones or all of the first discharge current, the second discharge current, the third discharge current and the fourth discharge current may as well be enabled until a first electric charge quantity, a second electric charge quantity, a third electric charge quantity or a fourth electric charge quantity. It is withdrawn from the corresponding first, second, third or fourth battery cell. This means that the cut-off voltages or the cut-off times are replaced by corresponding cut-off charge quantities.

In the above examples and variants of the method for operating a battery system and the battery system, single battery cells C1 to CN being equipped with a respective cell-level inverter units I1 to IN have been mentioned. It is understood that in an alternative it is also possible to provide one cell-level inverter unit for a group of battery cells respectively. The above explanations and effects also apply to this alternative. Other variations to the disclosed examples can be understood and effected by those skilled in the art in practicing the claimed disclosure, from the study of the drawings, the disclosure, and the appended claims. In the claims the word “comprising” does not exclude other elements or steps and the indefinite article “a” or “an” does not exclude a plurality. A single processor or other unit may fulfill the functions of several items or steps recited in the claims. The mere fact that certain measures are recited in mutually different dependent claims does not indicate that a combination of these measures cannot be used to advantage. A computer program may be stored/distributed on a suitable medium such as an optical storage medium or a solid-state medium supplied together with or as part of other hardware, but may also be distributed in other forms, such as via the Internet or other wired or wireless telecommunication systems. Any reference signs in the claims should not be construed as limiting the scope of the claims.

As used herein, the terms “first,” “second,” “third,” and the like in the description and in the claims, if any, distinguish between similar elements and do not necessarily describe a particular sequence or chronological order. The terms are interchangeable under appropriate circumstances such that the embodiments herein are, for example, capable of operation in sequences other than those illustrated or otherwise described herein. Furthermore, the terms “include,” “have,” and any variations thereof, cover a non-exclusive inclusion such that a process, method, system, article, device, or apparatus that comprises a list of elements is not necessarily limiting to those elements, but may include other elements not expressly listed or inherent to such process, method, system, article, device, or apparatus.

A computer program (also known as a program, software, software application, script, or code) is written in any appropriate form of programming language, including compiled or interpreted languages. Any appropriate form, including a standalone program or a module, component, subroutine, or other unit suitable for use in a computing environment may deploy it. A computer program does not necessarily correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may execute on one computer or on multiple computers that are located at one site or distributed across multiple sites and interconnected by a communication network.

A computing device or system may include a back-end component, e.g., a data server, or that includes a middleware component, e.g., an application server, or that includes a front-end component, e.g., a client computer having a graphical user interface or a Web browser through which a user may interact with an implementation, or any appropriate combination of one or more such back-end, middleware, or front-end components, may realize implementations described herein. Any appropriate form or medium of digital data communication, e.g., a communication network may interconnect the components of the system. Examples of communication networks include a Local Area Network (LAN) and a Wide Area Network (WAN), e.g., Intranet and Internet.

The term “computing system” encompasses all apparatus, devices, and machines for processing data, including by way of example, a programmable processor, a computer, or multiple processors or computers. The apparatus may include, in addition to hardware, code that creates an execution environment for the computer program in question, e.g., code that constitutes processor firmware, a protocol stack, a database management system, an operating system, or a combination of one or more of them. A propagated signal is an artificially generated signal (e.g., a machine-generated electrical, optical, or electromagnetic signal) that encodes information for transmission to a suitable receiver apparatus.

The computing system may include clients and servers. A client and server are remote from each other and typically interact through a communication network. The relationship of the client and server arises by virtue of computer programs running on the respective computers and having a client-server relationship with each other.

As used herein the term “component” refers to a distinct and identifiable part, element, subsystem, or unit within a larger system, structure, or entity. It is a building block that serves a specific function or purpose within a more complex whole. Components are often designed to be modular and interchangeable, allowing them to be combined or replaced in various configurations to create or modify systems. Components may be a combination of mechanical, electrical, hardware, firmware, software and/or other engineering elements.

The terms “non-transitory computer-readable medium” and “computer-readable medium” include a single medium or multiple media such as a centralized or distributed database, and/or associated caches and servers that store one or more sets of instructions. Further, the terms “non-transitory computer-readable medium” and “computer-readable medium” include any tangible medium that is capable of storing, encoding, or carrying a set of instructions for execution by a processor that, for example, when executed, cause a system to perform any one or more of the methods or operations disclosed herein. As used herein, the term “computer readable medium” is expressly defined to include any type of computer readable storage device and/or storage disk and to exclude propagating signals.

In addition, a non-transitory machine-readable medium and/or a system may embody the various operations, processes, and methods disclosed herein. Accordingly, the specification and drawings are illustrative rather than restrictive.

Physical computer-readable storage media includes RAM, ROM, EEPROM, CD-ROM or other optical disk storage (such as CDs, DVDs, etc.), magnetic disk storage or other magnetic storage devices, solid-state disks or any other medium. They store desired program code in the form of computer-executable instructions or data structures which can be accessed by a general purpose or special purpose computer.

Computer-executable instructions comprise, for example, instructions and data which cause a general purpose computer, special purpose computer, or special purpose processing device to perform a certain function or group of functions. The computer-executable instructions may be, for example, binary, intermediate format instructions such as assembly language, or even source code. Although the subject matter herein described is in a language specific to structural features and/or methodological acts, the described features or acts described do not limit the subject matter defined in the claims. Rather, the herein described features and acts are example forms of implementing the claims.

Further, a computer system including one or more processors and computer-readable media such as computer memory may practice the methods. In particular, one or more processors execute computer-executable instructions, stored in the computer memory, to perform various functions such as the acts recited in the embodiments.

As used herein the term “data processing unit” may be used interchangeably with processor in many contexts. Both terms generally refer to a component or unit within a computing system that is responsible for carrying out operations on data. The processor, or central processing unit (CPU), is an element of a computer that performs arithmetic and logic operations, executes instructions from computer programs, and manages data movement within the system.

One or more programmable processors, executing one or more computer programs to perform functions by operating on input data and generating output, perform the processes and logic flows described in this specification. The processes and logic flows may also be performed by, and apparatus may also be implemented as, special purpose logic circuitry, for example, without limitation, a Field Programmable Gate Array (FPGA), an Application Specific Integrated Circuit (ASIC), Application Specific Standard Products (ASSPs), System-On-a-Chip (SOC) systems, Complex Programmable Logic Devices (CPLDs), etc.

Processors suitable for the execution of a computer program include, by way of example, both general and special purpose microprocessors, and any one or more processors of any appropriate kind of digital computer. A processor will receive instructions and data from a read-only memory or a random-access memory or both. Elements of a computer can include a processor for performing instructions and one or more memory devices for storing instructions and data. A computer will also include, or is operatively coupled to receive data, transfer data or both, to/from one or more mass storage devices for storing data e.g., magnetic disks, magneto optical disks, optical disks, or solid-state disks. However, a computer need not have such devices. Moreover, another device, e.g., a mobile telephone, a personal digital assistant (PDA), a mobile audio player, a Global Positioning System (GPS) receiver, etc. may embed a computer. Computer-readable media suitable for storing computer program instructions and data include all forms of non-volatile memory, media and memory devices, including, by way of example, semiconductor memory devices (e.g., Erasable Programmable Read-Only Memory (EPROM), Electronically Erasable Programmable Read-Only Memory (EEPROM), and flash memory devices), magnetic disks (e.g., internal hard disks or removable disks), magneto optical disks (e.g. Compact Disc Read-Only Memory (CD ROM) disks, Digital Versatile Disk-Read-Only Memory (DVD-ROM) disks) and solid-state disks. Special purpose logic circuitry may supplement or incorporate the processor and the memory.

Digital electronic circuitry, or in computer software, firmware, or hardware, including the structures disclosed in this specification and their structural equivalents, or in combinations of one or more of them may realize the implementations and all of the functional operations described in this specification. Implementations may be as one or more computer program products i.e., one or more modules of computer program instructions encoded on a computer-readable medium for execution by, or to control the operation of, data processing apparatus. The computer-readable medium may be a machine-readable storage device, a machine-readable storage substrate, a memory device, a composition of matter affecting a machine-readable propagated signal, or a combination of one or more of them. The term “computing system” encompasses all apparatus, devices, and machines for processing data, including by way of example, a programmable processor, a computer, or multiple processors or computers. The apparatus may include, in addition to hardware, code that creates an execution environment for the computer program in question, e.g., code that constitutes processor firmware, a protocol stack, a database management system, an operating system, or a combination of one or more of them. A propagated signal is an artificially generated signal (e.g., a machine-generated electrical, optical, or electromagnetic signal) that encodes information for transmission to a suitable receiver apparatus.

Aspects of the one or more embodiments described herein are described with reference to flowchart illustrations and/or block diagrams of methods, apparatus (systems), and computer program products according to one or more embodiments described herein. Each block of the flowchart illustrations and/or block diagrams, and combinations of blocks in the flowchart illustrations and/or block diagrams, can be implemented by computer readable program instructions. These computer readable program instructions can be provided to a processor of a general purpose computer, special purpose computer and/or other programmable data processing apparatus to produce a machine, such that the instructions, which execute via the processor of the computer or other programmable data processing apparatus, can create means for implementing the functions/acts specified in the flowchart and/or block diagram block or blocks. These computer readable program instructions can also be stored in a computer readable storage medium that can direct a computer, a programmable data processing apparatus and/or other devices to function in a particular manner, such that the computer readable storage medium having instructions stored therein can comprise an article of manufacture including instructions which can implement aspects of the function/act specified in the flowchart and/or block diagram block or blocks. The computer readable program instructions can also be loaded onto a computer, other programmable data processing apparatus and/or other device to cause a series of operational acts to be performed on the computer, other programmable apparatus and/or other device to produce a computer implemented process, such that the instructions which execute on the computer, other programmable apparatus and/or other device implement the functions/acts specified in the flowchart and/or block diagram block or blocks.

While this specification contains many specifics, these do not construe as limitations on the scope of the disclosure or of the claims, but as descriptions of features specific to particular implementations. A single implementation may implement certain features described in this specification in the context of separate implementations. Conversely, multiple implementations separately or in any suitable sub-combination may implement various features described herein in the context of a single implementation. Moreover, although features described herein as acting in certain combinations and even initially claimed as such, one or more features from a claimed combination may in some cases be excised from the combination, and the claimed combination may be directed to a sub-combination or variation of a sub-combination.

Similarly, while operations depicted herein in the drawings in a particular order to achieve desired results, this should not be understood as requiring that such operations be performed in the particular order shown or in sequential order or that all illustrated operations be performed, to achieve desirable results. In certain circumstances, multitasking and parallel processing may be advantageous. Moreover, the separation of various system components in the implementations should not be understood as requiring such separation in all implementations, and it should be understood that the described program components and systems may be integrated together in a single software product or packaged into multiple software products.

Even though particular combinations of features are recited in the claims and/or disclosed in the specification, these combinations are not intended to limit the disclosure of possible implementations. Other implementations are within the scope of the claims. For example, the actions recited in the claims may be performed in a different order and still achieve desirable results. In fact, many of these features may be combined in ways not specifically recited in the claims and/or disclosed in the specification. Although each dependent claim may directly depend on only one claim, the disclosure of possible implementations includes each dependent claim in combination with every other claim in the claim set.

### LIST OF REFERENCE SIGNS

10 vehicle
12 drivetrain
14 rear wheels
16 battery system
18 electric traction motor
20 data processing apparatus
22 data processing unit
24 data storage unit
26 computer-readable storage medium
28 computer program
30 means for carrying out the method for operating a battery system
C1 to CN battery cell
I1 to IN cell-level inverter unit
OCV open circuit voltage
R1 row of battery cells
R2 row of battery cells
V1 first operational voltage
V2 second operational voltage
V3 third operational voltage
V4 fourth operational voltage
VC1 first cut-off voltage
VC2 second cut-off voltage
VC3 third cut-off voltage
VC4 fourth cut-off voltage
VC cut-off voltage

What is claimed is:

1. A method comprising:
requesting a first cell level inverter unit to enable a first discharge current and a second cell level inverter unit to disable a second discharge current, and
requesting the second cell level inverter unit to enable the second discharge current and the first cell level inverter unit to disable the first discharge current; and
wherein the method is operable for operating a battery system comprising a plurality of battery cells comprising a first single battery cell and a second single battery cell and a plurality of cell level inverter units comprising the first cell level inverter unit and the second cell level inverter unit; and
wherein each of a cell level inverter unit of the plurality of cell level inverter units being electrically coupled to at least a single battery cell out of the plurality of battery cells.

2. The method of claim 1, wherein requesting the first cell level inverter unit to enable the first discharge current and requesting the second cell level inverter unit to enable the second discharge current is performed in accordance with a predefined pattern.

3. The method of claim 1, wherein at least the first discharge current and the second discharge current is enabled for a predefined time.

4. The method of claim 1, wherein the first discharge current is enabled until a first operational voltage of the first single battery cell falls below a predefined first cut off voltage.

5. The method of claim 1, wherein the second discharge current is enabled until a second operational voltage of the second single battery cell falls below a predefined second cut off voltage.

6. The method of claim 1, wherein the first discharge current is enabled until a first electric charge quantity is withdrawn from the first single battery cell.

7. The method of claim 1, wherein the second discharge current is enabled until a second electric charge quantity is withdrawn from the second single battery cell.

8. The method of claim 1, wherein the first single battery cell and the second single battery cell are arranged adjacent to one another.

9. The method of claim 1, wherein the method is further operable to at least one of determine an environmental temperature and receive the environmental temperature.

10. The method of claim 9, wherein the method is executed when the environmental temperature is inferior to an environmental temperature threshold.

11. The method of claim 1, wherein the method is further operable to at least one of determine a battery system temperature and receive the battery system temperature.

12. The method of claim 11, wherein the method is executed when the battery system temperature is inferior to a battery system temperature threshold.

13. The method of claim 1, wherein the plurality of battery cells further comprises third single battery cell and the plurality of cell level inverter units further comprises a third cell level inverter unit and, wherein requesting the third cell level inverter unit that is electrically coupled to the third single battery cell, to enable a third discharge current originating from the third single battery cell, and further requesting the first cell level inverter unit to disable the first discharge current, and requesting the second cell level inverter unit to disable the second discharge current.

14. A system comprising,
a plurality of battery cells comprising a first single battery cell and a second single battery cell and a plurality of cell level inverter units comprising a first cell level inverter unit and a second cell level inverter unit, wherein each of a cell level inverter unit out of the plurality of cell level inverter units is electrically coupled to at least a single battery cell out of the plurality of battery cells; and
a data processing apparatus, wherein the data processing apparatus is communicatively coupled to one or more of the plurality of the cell level inverter units; and
wherein the data processing apparatus is operable to,
request the first cell level inverter unit to enable a first discharge current and the second cell level inverter unit to disable a second discharge current, and
request the second cell level inverter unit to enable the second discharge current and the first cell level inverter unit to disable the first discharge current; and
wherein the system is operable to be a battery system.

15. The system of claim 14, wherein the system is operable to be a component of a drivetrain, and wherein the drivetrain comprises an electric traction motor that is electrically coupled to the battery system.

16. The system of claim 15, wherein the drivetrain is operable to be a subsystem of a vehicle.

17. The system of claim 14, wherein a heat produced from withdrawing a discharge current from the first single battery cell is operable such that the heat warms the second single battery cell before a discharge current is withdrawn from the second single battery cell.

18. The system of claim 14, wherein the plurality of battery cells are arranged in one or more rows.

19. The system of claim 14, wherein each of a cell level inverter unit of the plurality of cell level inverter units is operable to convert a direct current signal being provided by an associated battery cell of the plurality of battery cells into one of an alternating current signal and a group of alternating current signals.

20. A non-transitory computer readable medium operations having stored thereon instructions executable by a computer system to perform operations comprising:
requesting a first cell level inverter unit to enable a first discharge current and a second cell level inverter unit to disable a second discharge current, and
requesting the second cell level inverter unit to enable the second discharge current and the first cell level inverter unit to disable the first discharge current; and
wherein the instructions are operable for operating a battery system comprising a plurality of battery cells comprising a first single battery cell and a second single battery cell; and a plurality of cell level inverter units comprising the first cell level inverter unit and the second cell level inverter unit; and
wherein each of a cell level inverter unit of the plurality of cell level inverter units being electrically coupled to at least a single battery cell out of the plurality of battery cells.
